(19) United States
(12) Patent Application Publication
(10) Pub. No.: US 2025/0185353 A1
(43) Pub. Date: Jun. 5, 2025

(54) Transistors with Different Drive Current Characteristics in Semiconductor Devices

(71) Applicant: Taiwan Semiconductor Manufacturing Company Ltd., Hsinchu (TW)

(72) Inventors: Sheng-Tsung Wang, Hsinchu (TW); Chun-Yuan Chen, Hsinchu (TW); Huan-Chieh Su, Tianzhong Township (TW); Lo-Heng Chang, Hsinchu (TW); Kuo-Cheng Chiang, Hsinchu (TW); Chih-Hao Wang, Hsinchu (TW)

(73) Assignee: Taiwan Semiconductor Manufacturing Company Ltd., Hsinchu (TW)

(21) Appl. No.: 18/756,449

(22) Filed: Jun. 27, 2024

Related U.S. Application Data
(60) Provisional application No. 63/604,993, filed on Dec. 1, 2023.

(51) Int. Cl. H01L 27/088; H01L 21/8234; H01L 23/528; H01L 29/06; H01L 29/08; H01L 29/417; H01L 29/423; H01L 29/66; H01L 29/775; H01L 29/786

(52) U.S. Cl. CPC H10D 84/83; H01L 23/5286; H10D 30/014; H10D 30/43; H10D 30/6729; H10D 30/6735; H10D 30/6757; H10D 62/121; H10D 62/151; H10D 64/017; H10D 84/0128; H10D 84/013; H10D 84/0149; H10D 84/038

(57) ABSTRACT

A semiconductor device and a method of fabricating the semiconductor device are disclosed. The semiconductor device includes first and second dummy epitaxial layers disposed in first and second base structures, first and second active epitaxial layers disposed on the first and second dummy epitaxial layers, a first active nanostructured layer disposed adjacent to and in contact with the first active epitaxial layer, a second active nanostructured layer disposed adjacent to and in contact with the second active epitaxial layer, a dummy nanostructured layer disposed adjacent to and in contact with the second dummy epitaxial layer, a first gate structure surrounding the first active nanostructured layer, and a second gate structure surrounding the second active nanostructured layer and the dummy nanostructured layer.

### CROSS-REFERENCE TO RELATED APPLICATION

This application claims the benefit of U.S. Provisional Patent Application No. 63/604,993, titled “Hybrid Sheet with Back-side Self-aligned Via and Back-side Isolation,” filed Dec. 1, 2023, which is incorporated by reference herein in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (finFETs), and gate-all-around field effect transistors (GAA FETs). Such scaling down has increased the complexity of semiconductor manufacturing processes.

### BRIEF DESCRIPTION OF THE DRAWINGS

Aspects of this disclosure are best understood from the following detailed description when read with the accompanying figures.

FIG. 1 illustrates an isometric view of a semiconductor device, in accordance with some embodiments.

FIGS. 2A-6A and 2B-6B illustrate different cross-sectional views of a semiconductor device with transistors having different drive current characteristics, in accordance with some embodiments.

FIG. 7 is a flow diagram of a method for fabricating a semiconductor device with transistors having different drive current characteristics, in accordance with some embodiments.

FIGS. 8A-28A, and 8B-28B illustrate cross-sectional views of a semiconductor device with transistors having different drive current characteristics at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5-20% of the value (e.g., ±1%, ±2%, ±3%, ±4%, 5%, ±10%, ±10-15%, ±15-20% of the value). These values are merely examples and are not intended to be limiting. The terms “about” and “substantially” can refer to a percentage of the values as interpreted by those skilled in relevant art(s) in light of the teachings herein.

The GAA transistor structures may be patterned by any suitable method. For example, the structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor structure.

A GAA FET can include a base structure (also referred to as “a sheet base” and “a fin base”) disposed on a substrate, source/drain (S/D) regions disposed on the substrate, nanostructured layers disposed on the base structure and between the S/D regions, and a gate structure surrounding each of the nanostructured layers. The nanostructured layers between the S/D regions function as channel regions of the GAA FET and the drive current characteristics (e.g., drive current values) of the GAA FET can depend on the number of nanostructured layers between the S/D regions.

The present disclosure provides example structures of GAA FETs with different drive current characteristics on a same substrate of a semiconductor device and also provides examples methods of fabricating these GAA FETs. In some embodiments, a first GAA FET can have first nanostructured layers between a first pair of S/D regions and a second GAA FET can have second nanostructured layers between a second pair of S/D regions. The number of first nanostructured layers can be greater than the number of second nanostructured layers to achieve a higher drive current in the first GAA FET than in the second GAA FET. The semiconductor device can have GAA FETs of different drive current values to optimize the overall power consumption of the semiconductor device. In some embodiments, the number of first and second nanostructured layers that are in contact with the first and second pairs of S/D regions can be controlled with the use of first and second electrically inactive (“dummy”) epitaxial layers disposed below the first and second pairs of S/D regions. In some embodiments, the first and second dummy epitaxial layers can also be used to form self-aligned back-side contact structures on back-side surfaces of the first and second pairs of S/D regions. In some embodiments, the first and second dummy epitaxial layers can be replaced with back-side isolation layers to reduce current leakage from the first and second pairs of S/D regions to the substrate.

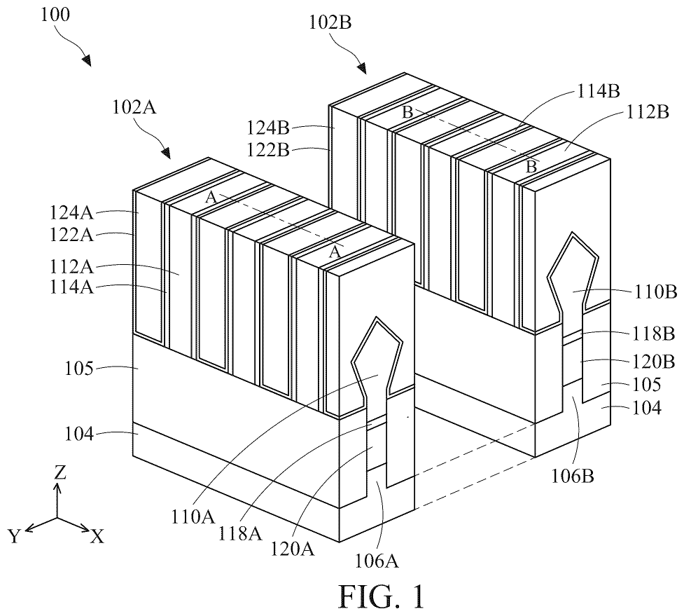

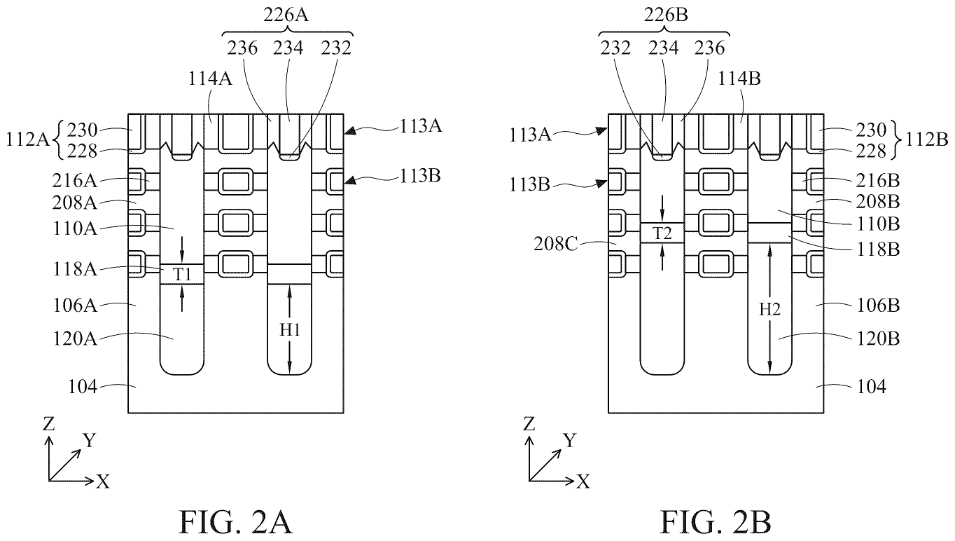

FIG. 1 illustrates an isometric view of a semiconductor device 100 with GAA FETs 102A and 102B, according to some embodiments. In some embodiments, GAA FETs 102A and 102B can be both p-type GAA FETs or n-type GAA FETs or can be one of each conductivity type GAA FETs. FIGS. 2A-6A illustrate different cross-sectional views of GAA FET 102A, along line A-A of FIG. 1, according to some embodiments. FIGS. 2B-6B illustrate different cross-sectional views of GAA FET 102B, along line B-B of FIG. 1, according to some embodiments. FIGS. 2A-6A and 2B-6B illustrate cross-sectional views with additional structures that are not shown in FIG. 1 for simplicity. The discussion of elements in FIGS. 1, 2A-6B, and 2B-6B with the same annotations applies to each other, unless mentioned otherwise.

Semiconductor device 100 can be formed on a substrate 104 with GAA FETs 102A and 102B formed on different regions of substrate 104. There may be other GAA FETs and/or structures (e.g., isolation structures) formed between GAA FETs 102A and 102B on substrate 104. In some embodiments, substrate 104 can be a semiconductor material, such as silicon (Si), Ge, silicon germanium (SiGe), a silicon-on-insulator (SOI) structure, and a combination thereof. Further, substrate 104 can be doped with p-type dopants (e.g., boron, indium, aluminum, or gallium) or n-type dopants (e.g., phosphorus or arsenic). Semiconductor device 100 can further include shallow trench isolation (STI) regions 105 disposed on substrate 104. In some embodiments, STI regions 105 can include an insulating material, such as silicon oxide (SiO₂), silicon nitride (SiN), silicon oxynitride (SiON), silicon oxycarbide (SiOC), silicon carbon nitride (SiCN), silicon oxycarbon nitride (SiOCN), and silicon germanium oxide (SiGeOₓ).

Referring to FIGS. 1 and 2A, in some embodiments, GAA FET 102A can include a fin-shaped base structure 106A (also referred to as a “sheet base 106A” or a “fin base 106A”) disposed on substrate 104, (ii) active nanostructured layers 208A disposed on base structure 106A, (iii) S/D regions 110A disposed adjacent to active nanostructured layers 208A, (iv) gate structures 112A surrounding active nanostructured layers 208A, (v) outer gate spacers 114A, (vi) inner gate spacers 216A, (vii) back-side (BS) etch stop layers (ESLs) 118A (also referred to as “capping layers 118A” or “seed layers 118A”), (viii) dummy epitaxial layers 120A, (ix) front-side (FS) ESLs 122A, (x) interlayer dielectric (ILD) layers 124A, and (xi) FS contact structures 226A.

Similarly, referring to FIGS. 1 and 2B, in some embodiments, GAA FET 102B can include a fin-shaped base structure 106B (also referred to as a “sheet base 106B” or “fin base 106B”) disposed on substrate 104, (ii) dummy nanostructured layers 208C disposed on base structure 106B, (iii) active nanostructured layers 208B disposed on dummy nanostructured layers 208C, (iv) S/D regions 110B disposed adjacent to active nanostructured layers 208B, (v) gate structures 112B surrounding active nanostructured layers 208B and dummy nanostructured layers 208C, (vi) outer gate spacers 114B, (vii) inner gate spacers 216B, (viii) BS ESLs 118B (also referred to as “capping layers 118B” or “seed layers 118B”), (ix) dummy epitaxial layers 120B, (x) FS ESLs 122B, (xi) ILD layers 124B, and (xii) FS contact structures 226B. In some embodiments, base structures 106A and 106B can include a material similar to substrate 104. Base structures 106A and 106B can have elongated sides extending along an X-axis.

Referring to FIGS. 2A and 2B, in some embodiments, active nanostructured layers 208A and 208B and dummy nanostructured layers 208C can be in the form of nanosheets, nanowires, nanorods, nanotubes, or other suitable nanostructured shapes. As used herein, the term “nanostructured” defines a structure, layer, and/or region as having a horizontal dimension (e.g., along an X- and/or Y-axis) and/or a vertical dimension (e.g., along a Z-axis) less than about 100 nm, for example about 90 nm, about 50 nm, about 10 nm, or other values less than about 100 nm. In some embodiments, active nanostructured layers 208A and 208B and dummy nanostructured layers 208C can include semiconductor materials similar to or different from substrate 104. In some embodiments, active nanostructured layers 208A and 208B and dummy nanostructured layers 208C can include Si, silicon arsenide (SiAs), silicon phosphide (SiP), silicon carbide (SiC), silicon carbon phosphide (SiCP), silicon germanium (SiGe), silicon germanium boron (SiGeB), germanium boron (GeB), silicon germanium stannum boron (SiGeSnB), a III-V semiconductor compound, or other suitable semiconductor materials.

In some embodiments, each of active nanostructured layers 208A and 208B and dummy nanostructured layers 208C can have a thickness of about 3 nm to about 15 nm along a Z-axis. Though rectangular cross-sections of active nanostructured layers 208A and 208B and dummy nanostructured layers 208C are shown, active nanostructured layers 208A and 208B and dummy nanostructured layers 208C can have cross-sections of other geometric shapes (e.g., circular, elliptical, triangular, or polygonal).

In some embodiments, active nanostructured layers 208A and 208B and dummy nanostructured layers 208C can be similar to each other in structure and composition, but can differ from each other functionally. As active nanostructured layers 208A are disposed between and in contact with S/D regions 110A, active nanostructured layers 208A can be electrically active and can function as channel regions of GAA FET 102A. Similarly, as active nanostructured layers 208B are disposed between and in contact with S/D regions 110B, active nanostructured layers 208B can be electrically active and can function as channel regions of GAA FET 102B. On the other hand, as dummy nanostructured layers 208C are not in contact with S/D regions 110B, dummy nanostructured layers 208C can be electrically inactive and does not function as channel regions of GAA FET 102B. Thus, even though both GAA FETs 102A and 102B have equal number of nanostructured layers between adjacent S/D regions, GAA FET 102A can have a larger number of active nanostructured layers (also referred to as “nanostructured channel regions”) than GAA FET 102B. Due to the number of active nanostructured layers 208A between adjacent S/D regions 110A being greater than the number of active nanostructured layers 208B between adjacent S/D regions 110B, GAA FET 102A can have a higher drive current than GAA FET 102B. Though three active nanostructured layers 208A are shown between adjacent S/D regions 110A and two active nanostructured layers 208B are shown between adjacent S/D regions 110B, GAA FETs 102A and 102B can have any number of active nanostructured layers 208A and 208B, except (i) the number of active nanostructured layers 208A between adjacent S/D regions 110A is greater than the number of active nanostructured layers 208B between adjacent S/D regions 110B, and (ii) the total number of active nanostructured layers 208A between adjacent S/D regions 110A is equal to the sum of active nanostructured layers 208B and dummy nanostructured layers 208C between adjacent S/D regions 110B.

Referring to FIGS. 1, 2A, and 2B, in some embodiments, S/D regions 110A and 110B (also referred to as “active epitaxial layers 110A and 110B”) can include an epitaxially-grown semiconductor material, such as Si, and n-type dopants, such as phosphorus, arsenic, and other suitable n-type dopants for n-type GAA FETs 102A and/or 102B. In some embodiments, n-type dopants can have a concentration of about 5×10¹⁹ cm⁻³ to about 5×10²¹ cm⁻³. S/D regions 110A and 110B can include an epitaxially-grown semiconductor material, such as Si and SiGe, and p-type dopants, such as boron and other suitable p-type dopants for p-type GAA FETs 102A and/or 102B. In some embodiments, p-type dopants can have a concentration of about 5×10¹⁹ cm⁻³ to about 5×10²¹ cm⁻³. Each of S/D regions 110A and 110B may refer to a source or a drain, individually or collectively dependent upon the context.

Referring to FIGS. 2A and 2B, in some embodiments, each of gate structures 112A and 112B can have an outer gate portion 113A and inner gate portions 113B. In some embodiments, the outer gate portions 113A can be disposed on and in physical contact with topmost active nanostructured layers 208A and 208B, respectively. In some embodiments, the inner gate portions 113B of gate structures 112A can be disposed between adjacent active nanostructured layers 208A and between adjacent inner gate spacers 216A. Similarly, in some embodiments, the inner gate portions 113B of gate structures 112B can be disposed between adjacent active nanostructured layers 208B and between adjacent inner gate spacers 216B.

Each of gate structures 112A and 112B can be multi-layered structures and can include (i) an interfacial oxide (IL) layer (not shown), (ii) a high-k (HK) gate dielectric layer 228, and (iii) a conductive layer 230. In some embodiments, IL layer can be disposed directly on topmost active nanostructured layers 208A and 208B. In some embodiments, IL layer can include SiO₂, SiGeOₓ, or germanium oxide (GeOₓ) and can have a thickness of about 1 nm to about 20 nm. In some embodiments, HK gate dielectric layer 228 can be disposed directly on IL layer and can include a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), and zirconium silicate (ZrSiO₂). In some embodiments, the sidewalls of IL layer and HK gate dielectric layer 228 can be in contact with sidewalls of outer gate spacers 114A and 114B.

In some embodiments, conductive layer 230 can be disposed on HK gate dielectric layer 228 and can be multi-layered structures. The different layers of conductive layer 230 are not shown for simplicity. In some embodiments, conductive layer 230 can include a work function metal (WFM) layer disposed on HK gate dielectric layer 230 and a gate metal fill layer disposed on the WFM layer. In some embodiments, the WFM layer can include substantially Al-free (e.g., with no Al) Ti-based or Ta-based nitrides or alloys, such as titanium nitride (TiN), titanium silicon nitride (TiSiN), titanium gold (Ti—Au) alloy, titanium copper (Ti—Cu) alloy, tantalum nitride (TaN), tantalum silicon nitride (TaSiN), tantalum gold (Ta—Au) alloy, and tantalum copper (Ta—Cu). In some embodiments, the WFM layer can include titanium aluminum (TiAl), titanium aluminum carbide (TiAlC), tantalum aluminum (TaAl), tantalum aluminum carbide (TaAlC), Al-doped Ti, Al-doped TiN, Al-doped Ta, Al-doped TaN, or other suitable Al-based materials. In some embodiments, the gate metal fill layer can include a suitable conductive material, such as tungsten (W), titanium (Ti), silver (Ag), ruthenium (Ru), molybdenum (Mo), copper (Cu), cobalt (Co), Al, iridium (Ir), nickel (Ni), metal alloys, and a combination thereof.

Referring to FIGS. 2A and 2B, outer gate spacers 114A and 114B can electrically isolate outer gate portions 113A from adjacent S/D regions 110A and 110B and form adjacent FS contact structures 226A and 226B. In some embodiments, outer gate spacers 114A and 114B can be disposed directly on topmost active nanostructured layers 208A and 208B, respectively. In some embodiments, outer gate spacers 114A and 114B can include a dielectric material, such as SiO₂, SiN, SiON, SiCN, SiOC, and SiOCN, and any other suitable dielectric material. Inner gate spacers 216A and 216B can electrically isolate the inner gate portions 113B from adjacent S/D regions 110A and 110B and can include a dielectric material, such as SiO₂, SiN, SiON, SiCN, SiOC, and SiOCN, and any other suitable dielectric material.

Referring to FIGS. 1, 2A, and 2B, in some embodiments, BS ESLs 118A and 118B can be disposed under and in contact with BS surfaces of S/D regions 110A and 110B, respectively. The sidewalls of BS ESLs 118A can be in contact with bottommost inner gate spacers 216A and base structure 106A. The sidewalls of BS ESLs 118B can be in contact with the sidewalls of dummy nanostructured layers 208C and bottommost inner gate spacers 216B. In some embodiments, BS ESLs 118A and 118B can include the same semiconductor material (e.g., Si or SiGe) as S/D regions 110A and 110B, respectively, and can function as seed layers for epitaxially growing S/D regions 110A and 110B. In some embodiments, BS ESLs 118A and 118B can include a dielectric material, such as SiN, SiON, SiCN, SiOC, and SiOCN, instead of semiconductor material, and can function as a barrier layer to prevent current leakage from S/D regions 110A and 110B to substrate 104. In some embodiments, BS ESLs 118A and 118B can have thicknesses T1 and T2 of about 1 nm to about 10 nm to adequately function as seed layers or barrier layers.

In some embodiments, dummy epitaxial layers 120A and 120B can be electrically inactive and can include undoped SiGe or SiGe doped with boron atoms. In some embodiments, the doped or undoped SiGe can have a Ge concentration of about 10 atomic % to about 50 atomic %. In some embodiments, dummy epitaxial layers 120A and 120B can be disposed under and in contact with BS surfaces of BS ESLs 118A and 118B, respectively. Dummy epitaxial layers 120A and 120B can be used to control the heights of S/D regions 110A and 110B. Controlling the heights of S/D regions 110A and 110B can control the number of nanostructures layers that are in contact with S/D regions 110A and 110B to form active nanostructured layers 208A and 208B. In GAA FET 102B, dummy epitaxial layers 120B along with BS ESLs 118B prevent S/D regions 110B from making contact with the bottommost nanostructured layers, which results in dummy nanostructured layers 208C. In some embodiments, dummy epitaxial layers 120A can have heights H1 smaller than heights H2 of dummy epitaxial layers 120B to form S/D regions 110A with heights greater than heights of S/D regions 110B. As a result, more nanostructured layers are in contact with S/D regions 110A than S/D regions 110B, thus forming a larger number of active nanostructured layers 208A than active nanostructured layers 208B. In some embodiments, heights H1 and H2 can be about 5 nm to about 70 nm. In some embodiments, for n-type doped S/D regions 110A and/or 110B, dummy epitaxial layers 120A and/or 120B can include undoped SiGe or doped SiGe.

In some embodiments, FS ESLs 122A and 122B (visible in FIG. 1; not visible in FIGS. 2A and 2B) can be disposed directly on FS surfaces of S/D regions 110A and 110B. In some embodiments, FS ESLs 122A and 122B can have a dielectric constant of about 4 to about 7 and can include a dielectric material, such as lanthanum oxide (LaO), aluminum oxide (Al₂O₃), yttrium oxide (Y₂O₃), tantalum carbon nitride (TaCN), zirconium silicide (ZrSi), SiOCN, SiOC, SiCN, zirconium nitride (ZrN), zirconium aluminum oxide (ZrAlO), TiO₂, Ta₂O₃, ZrO₂, HfO₂, SiN, hafnium silicide (HfSi), aluminum oxynitride (AlON), SiO₂, SiC, SiN, and zinc oxide (ZnO). In some embodiments, ILD layers 124A and 124B (visible in FIG. 1; not visible in FIGS. 2A and 2B) can be disposed directly on FS ESLs 122A and 122B. In some embodiments, ILD layers 124A and 124B can include an insulating material, such as SiO₂, SiN, SiON, SiCN, SiOC, and SiOCN.

In some embodiments, each of FS contact structures 226A and 226B can include (i) a silicide layer 232, (ii) a contact plug 234 disposed on silicide layer 232, and (iii) a dielectric liner 236 surrounding contact plug 234. In some embodiments, silicide layer 232 in n-type GAA FETs 102A and 102B can include titanium silicide (TiₓSi_{y}), tantalum silicide (TaₓSi_{y}), molybdenum (MoₓSi_{y}), zirconium silicide (ZrₓSi_{y}), hafnium silicide (HfₓSi_{y}), scandium silicide (ScₓSi_{y}), yttrium silicide (YₓSi_{y}), terbium silicide (TbₓSi_{y}), lutetium silicide (LuₓSi_{y}), erbium silicide (ErₓSi_{y}), ybtterbium silicide (YbₓSi_{y}), europium silicide (EuₓSi_{y}), thorium silicide (ThₓSi_{y}), other suitable metal silicide materials, or a combination thereof. In some embodiments, silicide layer 232 in p-type GAA FETs 102A and 102B can include nickel silicide (NiₓSi_{y}), cobalt silicide (CoₓSi_{y}), manganese silicide (MnₓSi_{y}), tungsten silicide (WₓSi_{y}), iron silicide (FeₓSi_{y}), rhodium silicide (RhₓSi_{y}), palladium silicide (PdₓSi_{y}), ruthenium silicide (RuₓSi_{y}), platinum silicide (PtₓSi_{y}), iridium silicide (IrₓSi_{y}), osmium silicide (OsₓSi_{y}), other suitable metal silicide materials, or a combination thereof. In some embodiments, contact plug 234 can include conductive materials, such as Co, W, Ru, Al, Mo, Ir, Ni, osmium (Os), rhodium (Rh), other suitable conductive materials, and a combination thereof. In some embodiments, dielectric liner 236 can include a dielectric material, such as SiN, SiON, SiCN, SiOC, and SiOCN.

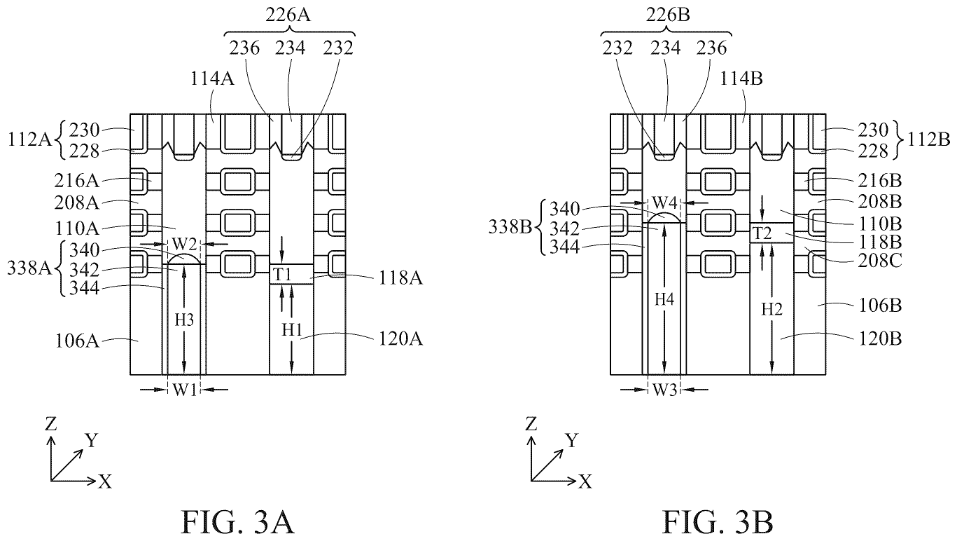

Referring to FIGS. 3A and 3B, in some embodiments, GAA FETs 102A and 102B can have BS contact structures 338A and 338B disposed on BS surfaces of one or more of S/D regions 110A and 110B instead of BS ESLs 118A and 118B and dummy epitaxial layers 120A and 120B of FIGS. 2A and 2B. BS contact structures 338A and 338B can electrically connect S/D regions 110A and 110B to BS power rail (not shown) disposed on BS contact structures 338A and 338B. The BS power rail can include metal lines (not shown) for providing power supply to S/D regions 110A and 110B through BS contact structures 338A and 338B. With the use of BS power rail, device area for placing interconnects between S/D regions 110A and 110B and power supplies can be reduced, thus reducing power consumption compared to other GAA FETs without BS power rails.

In some embodiments, each of BS contact structures 338A and 338B can include (i) a silicide layer 340, (ii) a contact plug 342 disposed on silicide layer 340, and (iii) a dielectric liner 344 surrounding contact plug 342. In some embodiments, silicide layer 340 can include TiₓSi_{y}, TaₓSi_{y}, MoₓSi_{y}, ZrₓSi_{y}, HfₓSi_{y}, ScₓSi_{y}, YₓSi_{y}, TbₓSi_{y}, LuₓSi_{y}, ErₓSi_{y}, YbₓSi_{y}, chromium silicide (CrₓSi_{y}), holmium silicide (HoₓSi_{y}), gadolinium silicide (GdₓSi_{y}), dysprosium silicide (DyₓSi_{y}), other suitable metal silicide materials, or a combination thereof. In some embodiments, silicide layers 340 can have a thickness of about 1 nm to about 10 nm to minimize contact resistance between S/D regions 110A and contact plugs 342 of BS contact structures 338A and between S/D regions 110B and contact plugs 342 of BS contact structures 338B. In some embodiments, contact plug 342 can include conductive materials, such as Co, W, Ru, Mo, Ir, Cu, other suitable conductive materials, and a combination thereof.

In some embodiments, contact plug 342 of BS contact structure 338A can have a height H3 of about 5 nm to about 70 nm and contact plug 342 of BS contact structure 338B can have a height H4 of about 5 nm to about 70 nm. In some embodiments, height H3 is smaller than height H4. As BS contact structures 338A and 338B are formed by replacing dummy epitaxial layers 120A and 120B (described in detail below), respectively, the relative relationship between heights H1 and H2 of dummy epitaxial layers 120A and 120B applies to the relative relationship between heights H3 and H4. In some embodiments, contact plug 342 of BS contact structure 338A can have a top surface width W1 of about 5 nm to about 50 nm and a bottom surface width W2 of about 5 nm to about 40 nm, which can be equal to or smaller than width W1. Similarly, contact plug 342 of BS contact structure 338B can have a top surface width W3 of about 5 nm to about 50 nm and a bottom surface width W4 of about 5 nm to about 40 nm, which can be equal to or smaller than width W3. In some embodiments, dielectric liner 344 can include a dielectric material, such as SiN, SiON, SiCN, SiOC, and SiOCN and can have a thickness of about 0.5 nm to about 5 nm.

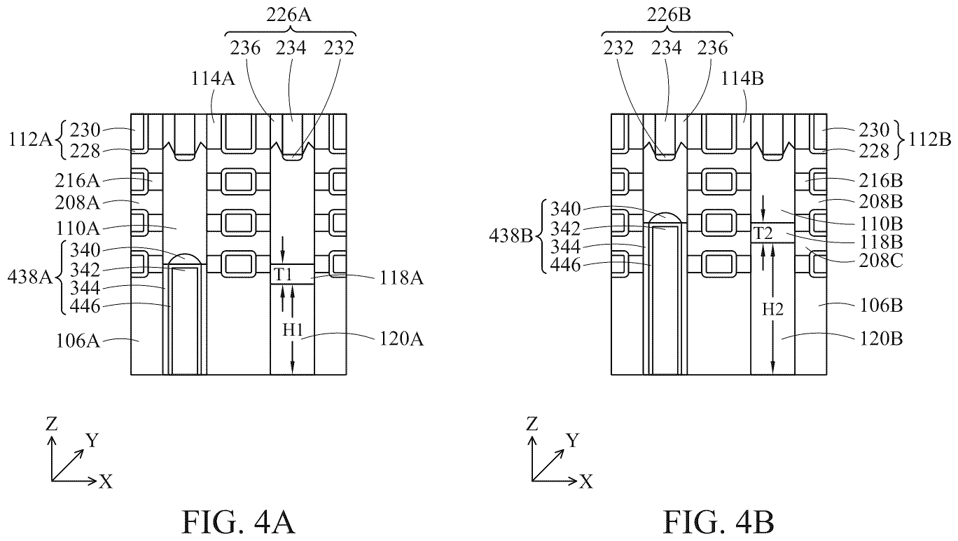

Referring to FIGS. 4A and 4B, in some embodiments, GAA FETs 102A and 102B can have BS contact structures 438A and 438B instead of BS contact structures 338A and 338B of FIGS. 3A and 3B. The discussion of BS contact structures 338A and 338B applies to BS contact structures 438A and 438B, unless mentioned otherwise. In some embodiments, each of BS contact structures 438A and 438B can include (i) silicide layer 340, (ii) a barrier layer 446 disposed on silicide layer 340, (iii) contact plug 342 disposed on inner sidewalls and bottom surface of barrier layer 446, and (iv) dielectric liner 344 disposed on outer sidewalls of barrier layer 446. In some embodiments, barrier layer 446 can prevent the oxidation of the metal of contact plug 342 and can include Ti, TiN, TaN, W, or Ru. In some embodiments, barrier layer 446 can have a thickness of about 0.1 nm to about 2 nm to adequately prevent the oxidation of the metal of contact plug 342.

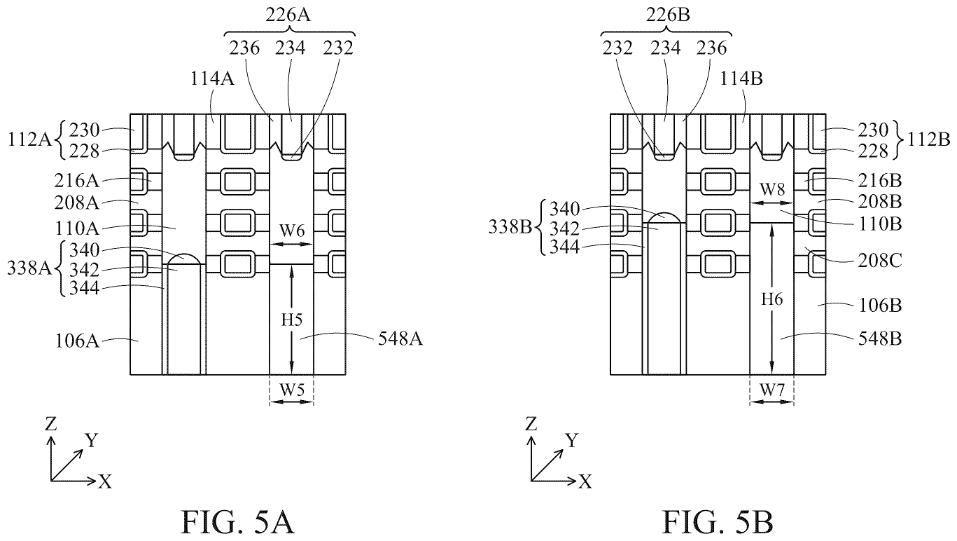

Referring to FIG. 5A, in some embodiments, GAA FET 102A can have BS contact structure 338A and BS isolation layer 548A disposed on BS surfaces of S/D regions 110A instead of BS ESLs 118A and dummy epitaxial layers 120A of FIG. 2A. Similarly, referring to FIG. 5B, GAA FET 102B can have BS contact structure 338B and BS isolation layer 548B disposed on BS surfaces of S/D regions 110B instead of BS ESLs 118B and dummy epitaxial layers 120B of FIG. 2B. In some embodiments, BS isolation layers 548A and 548B can electrically isolate S/D regions 110A and 110B from base structures 106A and 106B and/or from other BS structures (e.g., BS power rail; not shown) disposed on BS surfaces of base structures 106A and 106B. Also, BS isolation layer 548B and dielectric liner 344 of BS contact structure 338B can prevent S/D region 110B from making contact with dummy nanostructured layers 208C.

In some embodiments, BS isolation layers 548A and 548B can include a dielectric material, such as LaO, Al₂O₃, Y₂O₃, TaCN, SiOCN, SiOC, SiCN, TiO₂, Ta₂O₃, ZrO₂, ZrAlO, HfO₂, SiN, AlON, SiO₂, SiN, and ZnO. In some embodiments, BS isolation layers 548A and 548B can have heights H5 and H6 of about 5 nm to about 70. In some embodiments, height H5 is smaller than height H6. As BS isolation layers 548A and 548B are formed by replacing dummy epitaxial layers 120A and 120B (described in detail below), respectively, the relative relationship between heights H1 and H2 of dummy epitaxial layers 120A and 120B applies to the relative relationship between heights H5 and H6. In some embodiments, BS isolation layers 548A and 548B can have top surface widths W5 and W7 of about 5 nm to about 50 nm and bottom surface widths W6 and W8 of about 5 nm to about 50 nm, which can be equal to or smaller than widths W5 and W7.

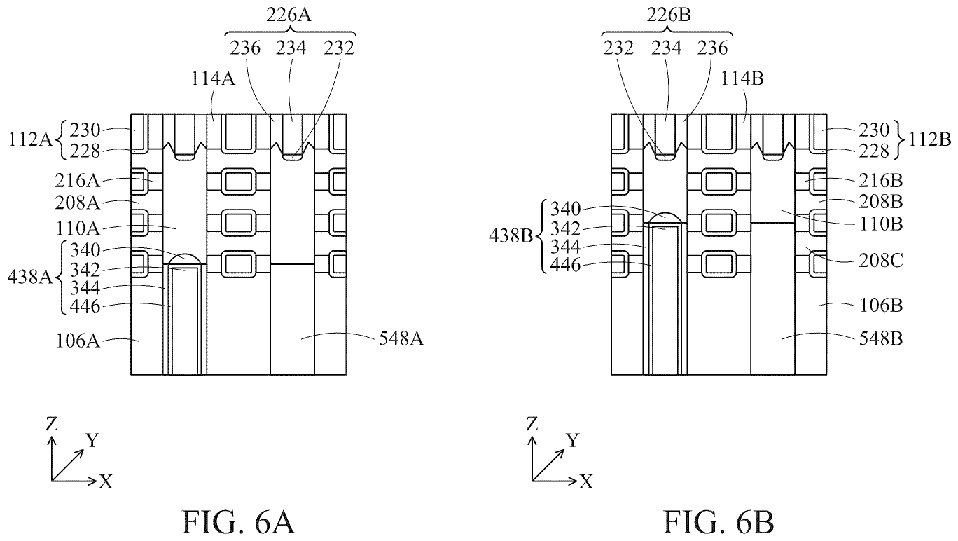

Referring to FIG. 6A, in some embodiments, GAA FET 102A can have BS contact structure 438A and BS isolation layer 548A disposed on BS surfaces of S/D regions 110A instead of BS ESLs 118A and dummy epitaxial layers 120A of FIG. 2A. Similarly, referring to FIG. 6B, GAA FET 102B can have BS contact structure 438B and BS isolation layer 548B disposed on BS surfaces of S/D regions 110B instead of BS ESLs 118B and dummy epitaxial layers 120B of FIG. 2B.

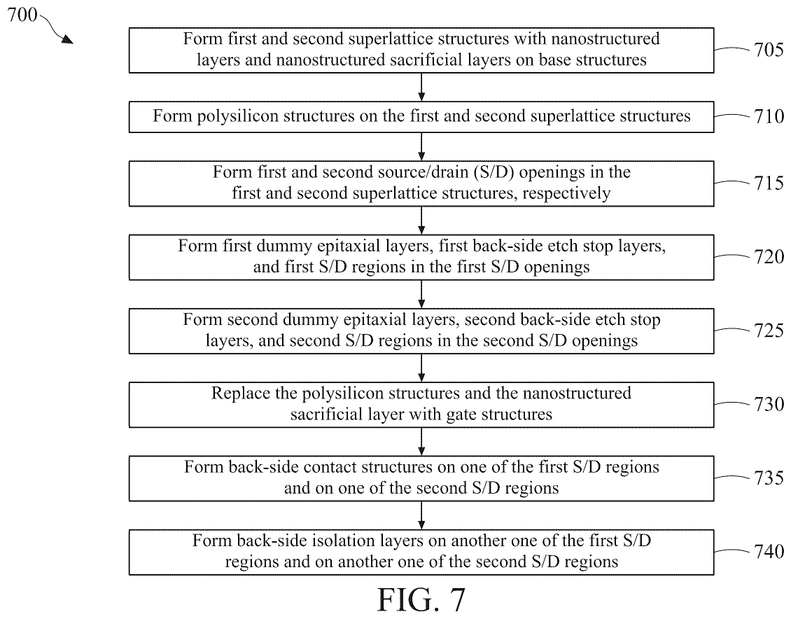

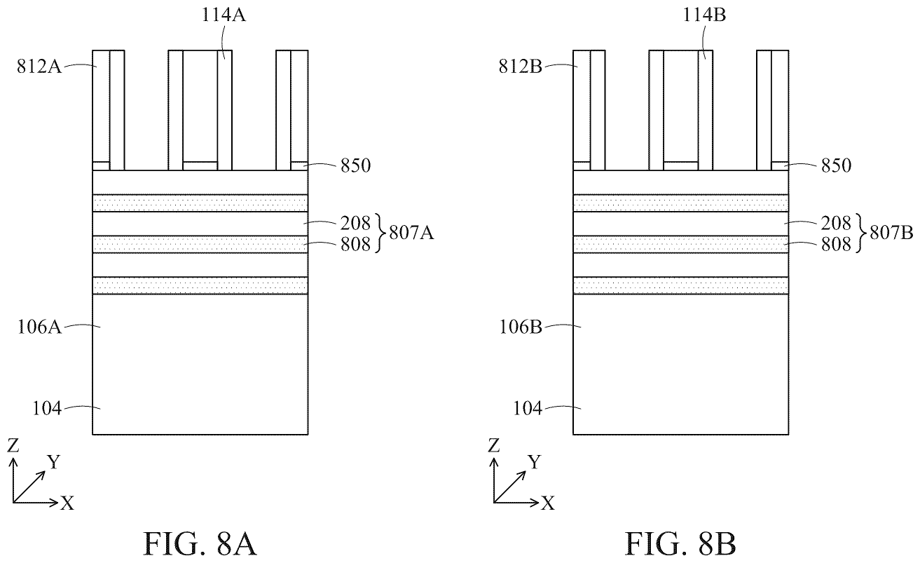

FIG. 7 is a flow diagram of an example method 700 for fabricating semiconductor device 100 with the cross-sectional views of FIGS. 2A-6A and 2B-6B, according to some embodiments. For illustrative purposes, the operations illustrated in FIG. 7 will be described with reference to the example fabrication process for fabricating semiconductor device 100 as illustrated in FIGS. 8A-28A and 8B-28B. FIGS. 8A-28A are cross-sectional views of semiconductor device 100 along line A-A of FIG. 1, and FIGS. 8B-28B are cross-sectional views of semiconductor device 100 along line B-B of FIG. 1 at various stages of fabrication of semiconductor device 100, according to some embodiments. Operations can be performed in a different order or not performed depending on specific applications. It should be noted that method 700 may not produce a complete semiconductor device 100. Accordingly, it is understood that additional processes can be provided before, during, and after method 700, and that some other processes may only be briefly described herein. The discussion of elements in FIGS. 1, 2A-6A, 2B-6B, 8A-28A, and 8B-28B with the same annotations applies to each other, unless mentioned otherwise.

Referring to FIG. 7, in operation 705, first and second superlattice structures with nanostructured layers and nanostructured sacrificial layers are formed on base structures. For example, as described with reference to FIGS. 8A and 8B, superlattice structures 807A and 807B (also referred to as “nanosheet stacks 807A and 807B”) are formed on base structures 106A and 106B, respectively, which are formed on substrate 104. Each of superlattice structures 807A and 807B can include nanostructured layers 208 and nanostructured sacrificial layers 808 arranged in an alternating configuration. In some embodiments, nanostructured layers 208 can include Si, and nanostructured sacrificial layers 808 can include SiGe.

Referring to FIG. 7, in operation 710, polysilicon structures are formed on the first and second superlattice structures. For example, as described with reference to FIGS. 8A and 8B, polysilicon structures 812A and 812B are formed on superlattice structures 807A and 807B, respectively. In some embodiments, SiO₂ layers 850 can be formed on superlattice structures 807A and 807B prior to the formation of polysilicon structures 812A and 812B. During subsequent processing, polysilicon structures 812A and 812B, SiO₂ layers 850, and nanostructured sacrificial layers 808 can be replaced with gate structures 112A and 112B in a gate replacement process. In some embodiments, the formation of polysilicon structures 812A and 812B can be followed by the formation of outer gate spacers 114A and 114B, as shown in FIGS. 8A and 8B.

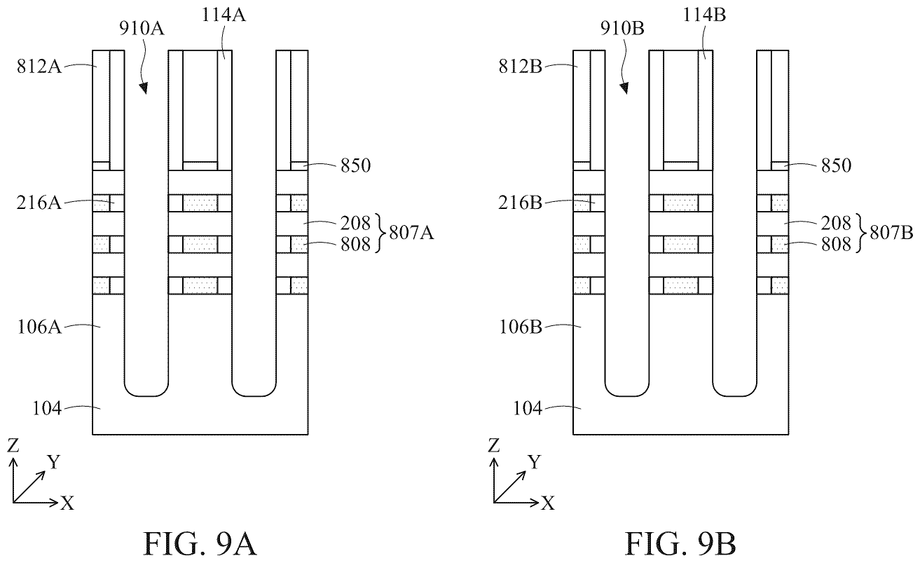

Referring to FIG. 7, in operation 715, first and second S/D openings are formed in the first and second superlattice structures. For example, as described with reference to FIGS. 9A and 9B, first S/D openings 910A are formed in superlattice structure 807A and second S/D openings 910B are formed in superlattice structure 807B. S/D openings 910A and 910B can be formed by etching the portions of superlattice structures 807A and 807B that are not covered by polysilicon structures 812A and 812B. In some embodiments, the etching of superlattice structures 807A and 807B can include a plasma-based dry etching process using etching gases, such as carbon tetrafluoride (CF₄), sulfur dioxide (SO₂), hexafluoroethane (C₂F₆), chlorine (Cl₂), nitrogen trifluoride (NF₃), sulfur hexafluoride (SF₆), and hydrogen bromide (HBr), with mixture gases, such as hydrogen (H₂), oxygen (O₂), nitrogen (N₂), and argon (Ar). The etching can be performed at a temperature ranging from about 25° C. to about 200° C. under a pressure from about 5 mTorr to about 50 mTorr. The flow rate of the etching gases can range from about 5 standard cubic centimeters per minute (sccm) to about 100 sccm. The plasma power can range from about 50 W to about 200 W with a bias voltage from about 30 V to about 200 V. In some embodiments, the formation of S/D openings 910A and 910B can be followed by the formation of inner gate spacers 216A and 216B, as shown in FIGS. 9A and 9B.

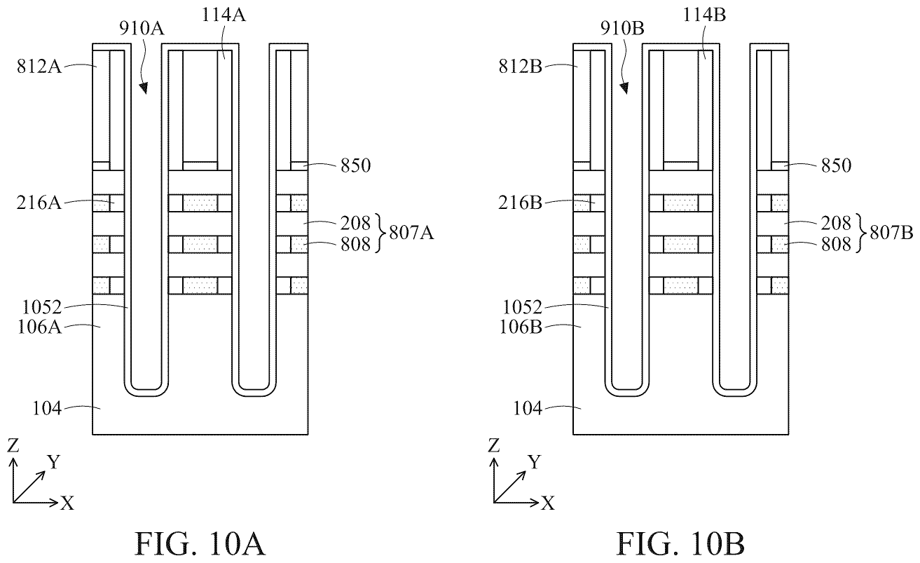

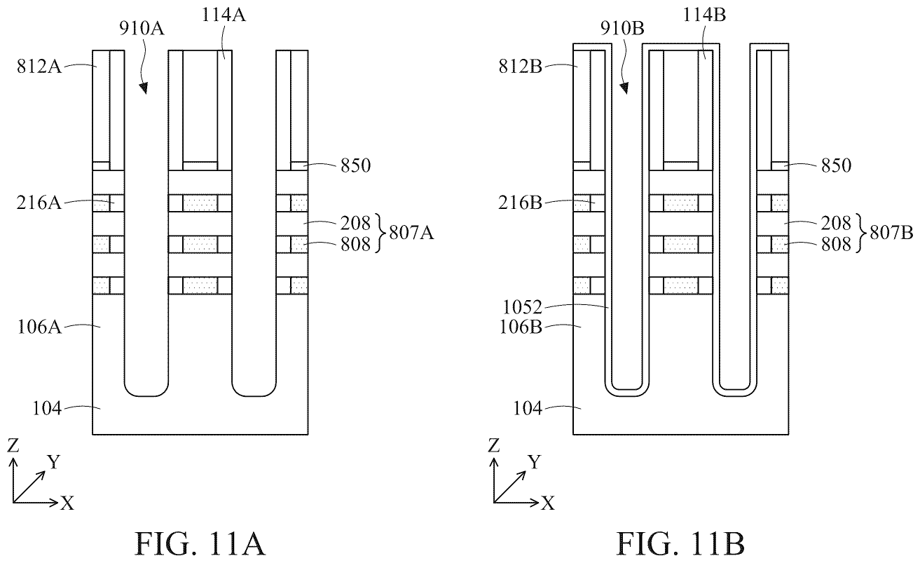

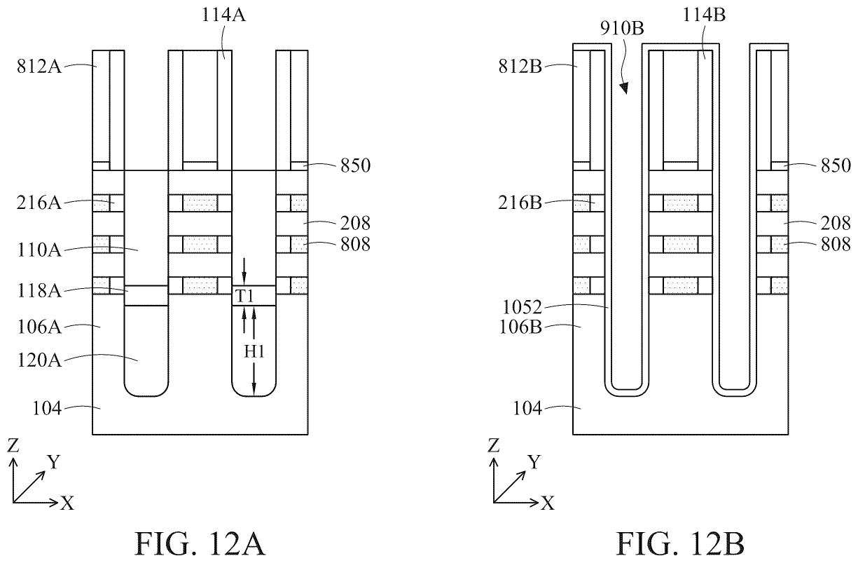

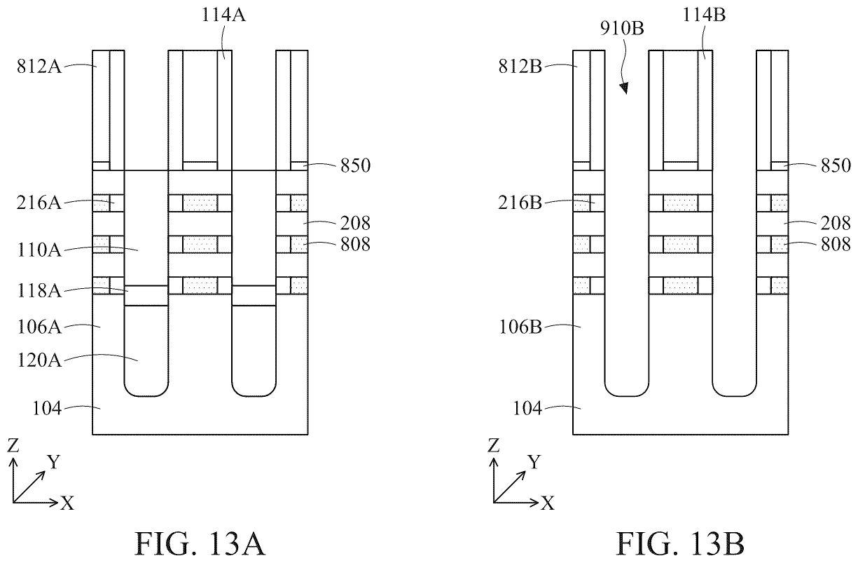

Referring to FIG. 7, in operation 720, first dummy epitaxial layers, first BS ESLs, and first S/D regions are formed in the first S/D openings. For example, as described with reference to FIGS. 10A-13A and 10B-13B, dummy epitaxial layers 120A, BS ESLs 118A, and S/D regions 110A are formed in S/D openings 910A. The formation of dummy epitaxial layers 120A, BS ESLs 118A, and S/D regions 110A can include sequential operations of (i) depositing a hard mask layer 1052 (e.g., a SiN layer) on the structures of FIGS. 9A and 9B to form the structures of FIGS. 10A and 10B, (ii) removing (e.g., by etching) the portion of hard mask layer 1052 on the structure of FIG. 10A without removing the portion of hard mask layer 1052 on the structure of FIG. 10B to form the structures of FIGS. 11A and 11B, (iii) epitaxially growing the semiconductor material (e.g., doped or undoped SiGe) of dummy epitaxial layers 120A to a height of H1 in S/D openings 910A, as shown in FIG. 12A, without growing the semiconductor material of dummy epitaxial layers 120A in S/D openings 910B, as shown in FIG. 12B, (iv) epitaxially growing or depositing BS ESLs 118A with a thickness of T1 on dummy epitaxial layers 120A, as shown in FIG. 12A, without growing BS ESLs 118A in S/D openings 910B, as shown in FIG. 12B, (v) epitaxially growing the semiconductor material (e.g., doped Si or doped SiGe) of S/D regions 110A on BS ESLs 118A, as shown in FIG. 12A, without growing the semiconductor material of S/D regions 110A in S/D openings 910B, as shown in FIG. 12B, and (vi) removing hard mask layer 1052 from the structure of FIG. 12B without etching S/D regions 110A to form the structures of FIGS. 13A and 13B. The dielectric material of hard mask layer 1052 on the structure of FIG. 12B prevents dummy epitaxial layers 120A, BS ESLs 118A, and S/D regions 110A from growing in S/D openings 910B, as shown in FIG. 12B. In some embodiments, BS ESLs 118A are epitaxially grown or deposited on dummy epitaxial layers 120A if BS ESLs 118A are formed with a semiconductor material. In some embodiments, BS ESLs 118A are deposited on dummy epitaxial layers 120A if BS ESLs 118A are formed with a dielectric material.

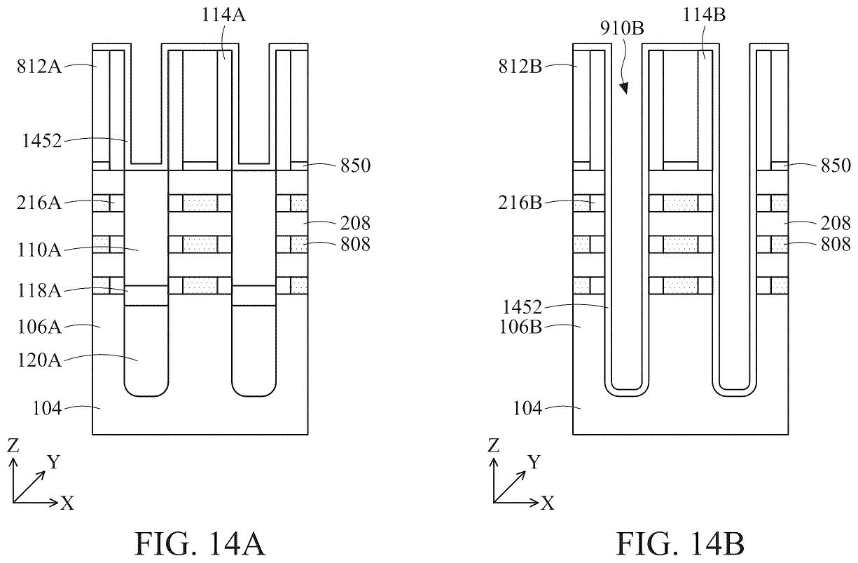

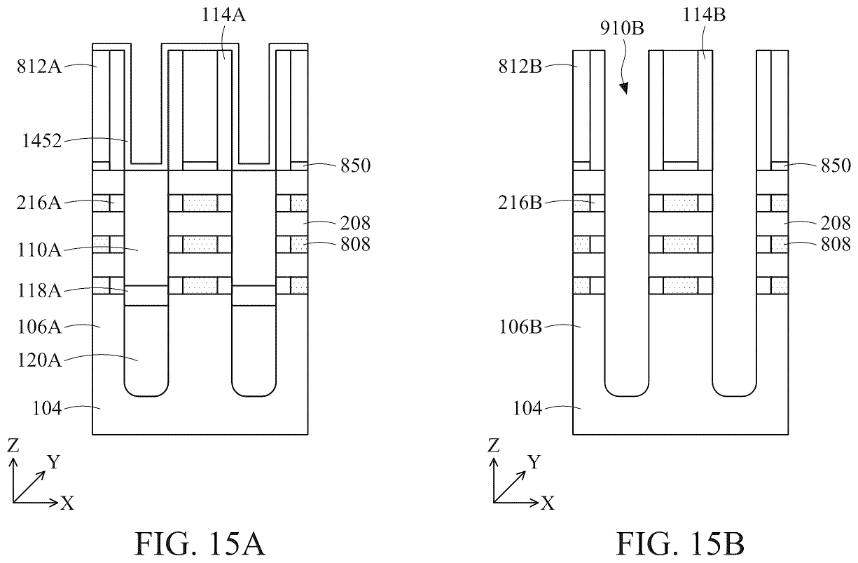

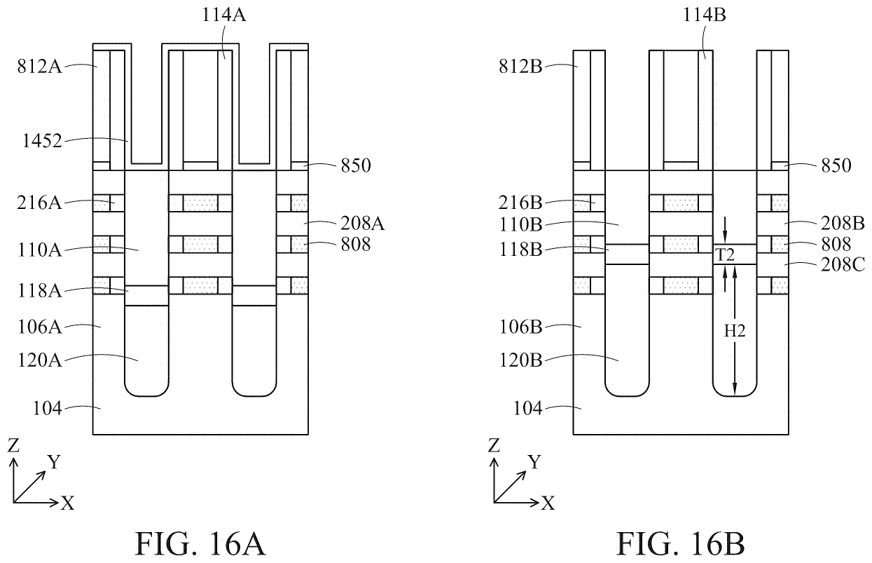

Referring to FIG. 7, in operation 725, second dummy epitaxial layers, second BS ESLs, and second S/D regions are formed in the second S/D openings. For example, as described with reference to FIGS. 14A-16A and 14B-16B, dummy epitaxial layers 120B, BS ESLs 118B, and S/D regions 110B are formed in S/D openings 910B. The formation of dummy epitaxial layers 120B, BS ESLs 118B, and S/D regions 110B can include sequential operations of (i) depositing a hard mask layer 1452 (e.g., a SiN layer) on the structures of FIGS. 13A and 13B to form the structures of FIGS. 14A and 14B, (ii) removing (e.g., by etching) the portion of hard mask layer 1452 on the structure of FIG. 14A without removing the portion of hard mask layer 1452 on the structure of FIG. 14B to form the structures of FIGS. 15A and 15B, (iii) epitaxially growing the semiconductor material (e.g., doped or undoped SiGe) of dummy epitaxial layers 120B to a height of H2 in S/D openings 910B, as shown in FIG. 16B, without growing the semiconductor material of dummy epitaxial layers 120B in S/D openings 910A, as shown in FIG. 16A, (iv) epitaxially growing or depositing BS ESLs 118B with a thickness of T2 on dummy epitaxial layers 120B, as shown in FIG. 16B, without growing BS ESLs 118B in S/D openings 910A, as shown in FIG. 16A, (v) epitaxially growing the semiconductor material (e.g., doped Si or doped SiGe) of S/D regions 110B on BS ESLs 118B, as shown in FIG. 16B, without growing the semiconductor material of S/D regions 110B in S/D openings 910A, as shown in FIG. 16A, and (vi) removing hard mask layer 1452 from the structure of FIG. 16B without etching S/D regions 110B. In some embodiments, BS ESLs 118B are epitaxially grown or deposited on dummy epitaxial layers 120B if BS ESLs 118B are formed with a semiconductor material. In some embodiments, BS ESLs 118B are deposited on dummy epitaxial layers 120B if BS ESLs 118B are formed with a dielectric material.

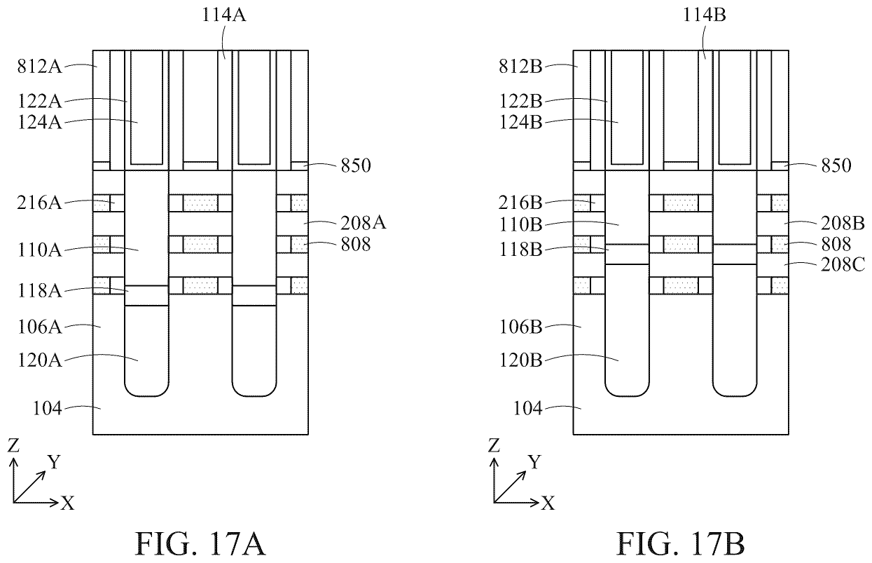

The growth of dummy epitaxial layers 120B to height of H2 and BS ESLs 118B with thickness of T2 prevents S/D regions 110B from being formed adjacent to and in contact with the bottommost nanostructured layers 208 of superlattice structure 807B. As a result, the bottommost nanostructured layers 208 of superlattice structure 807B form dummy nanostructured layers 208C and nanostructured layers 208 of superlattice structure 807B adjacent to and in contact with S/D regions 110B form active nanostructured layers 208B, as shown in FIG. 16B. The dielectric material of hard mask layer 1452 on the structure of FIG. 16A prevents dummy epitaxial layers 120B, BS ESLs 118B, and S/D regions 110B from growing on S/D regions 110A. The formation of S/D regions 110B can be followed by the formation of FS ESLs 122A and 122B and ILD layers 124A and 124B, as shown in FIGS. 17A and 17B.

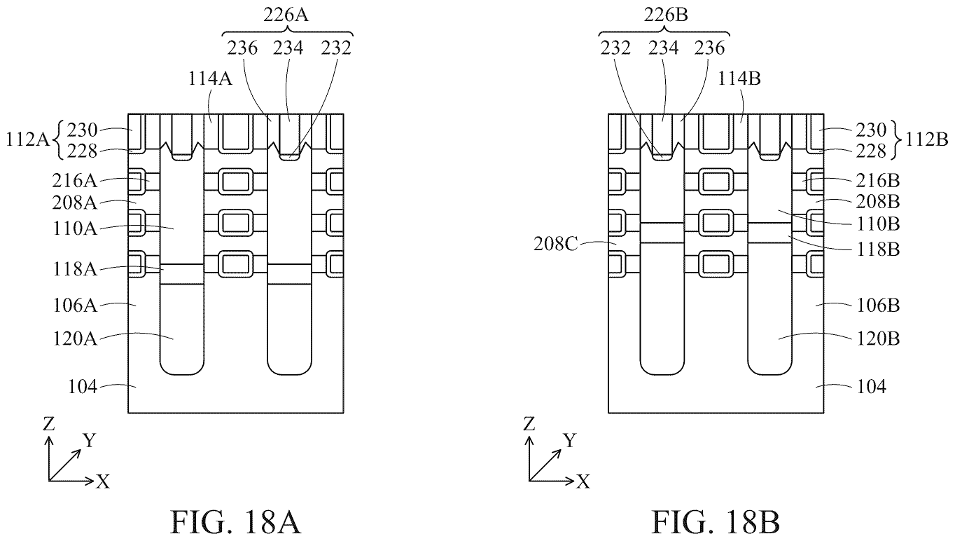

Referring to FIG. 7, in operation 730, the polysilicon structures and the nanostructured sacrificial layer are replaced with gate structures. For example, as described with reference to FIGS. 18A and 18B, polysilicon structures 812A and 812B and nanostructured sacrificial layers 808 are replaced with gate structures 112A and 112B. The formation of gate structures 112A and 112B can include (i) removing polysilicon structures 812A and 812B, SiO₂ layers 850, and nanostructured sacrificial layers 808 from the structures of FIGS. 17A and 17B to form gate openings (not shown), and (ii) forming gate structures 112A and 112B in the gate openings, as shown in FIGS. 18A and 18B. In some embodiments, the formation of gate structures 112A and 112B can be followed by the formation of FS contact structures 226A on S/D regions 110A and FS contact structures 226B on S/D regions 110B, as shown in FIGS. 18A and 18B.

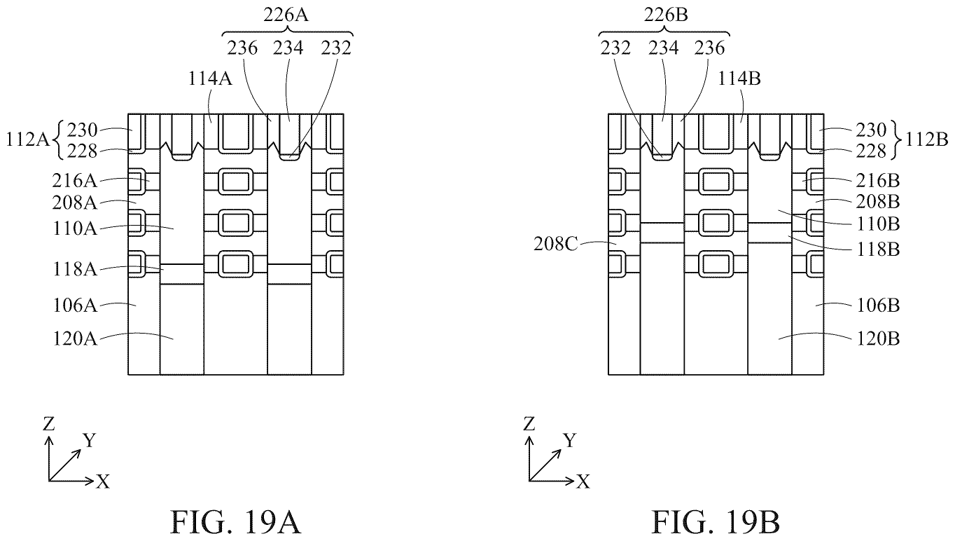

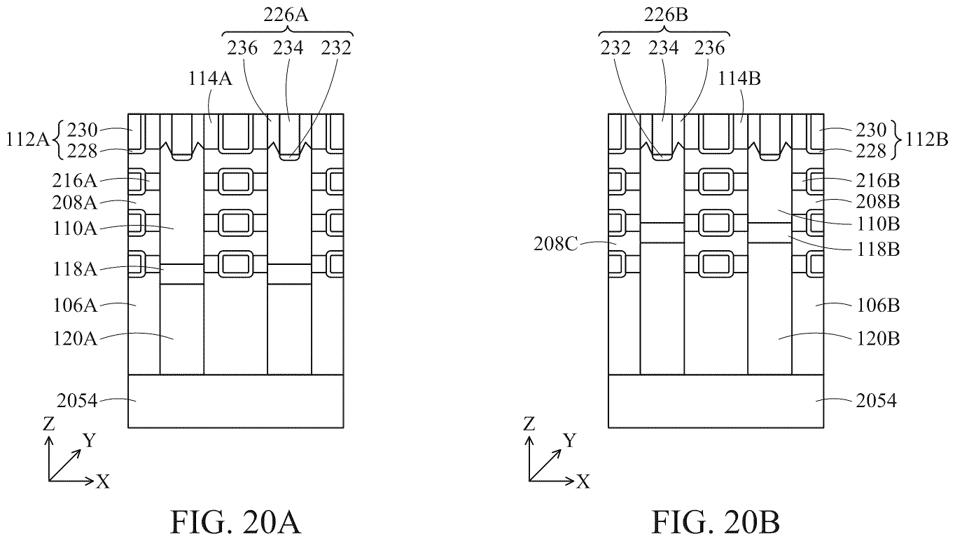

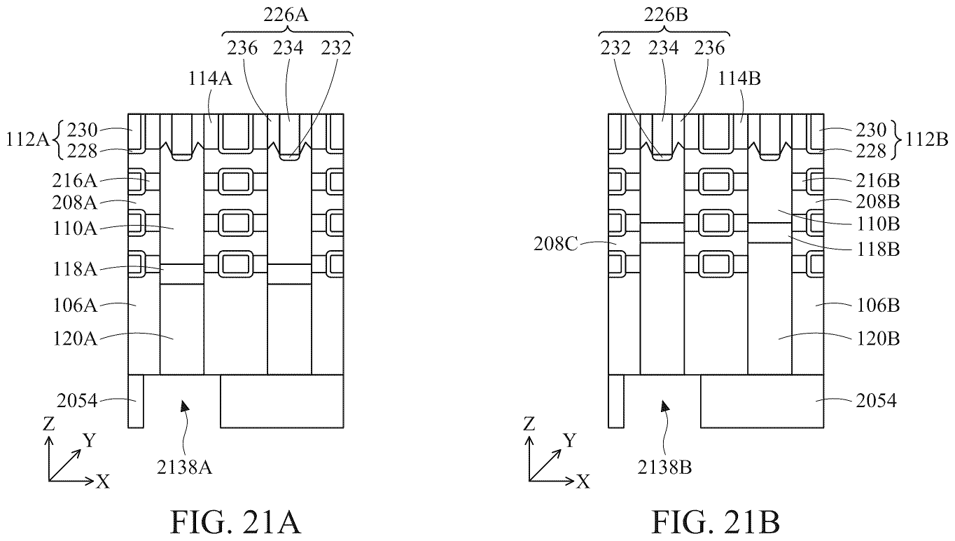

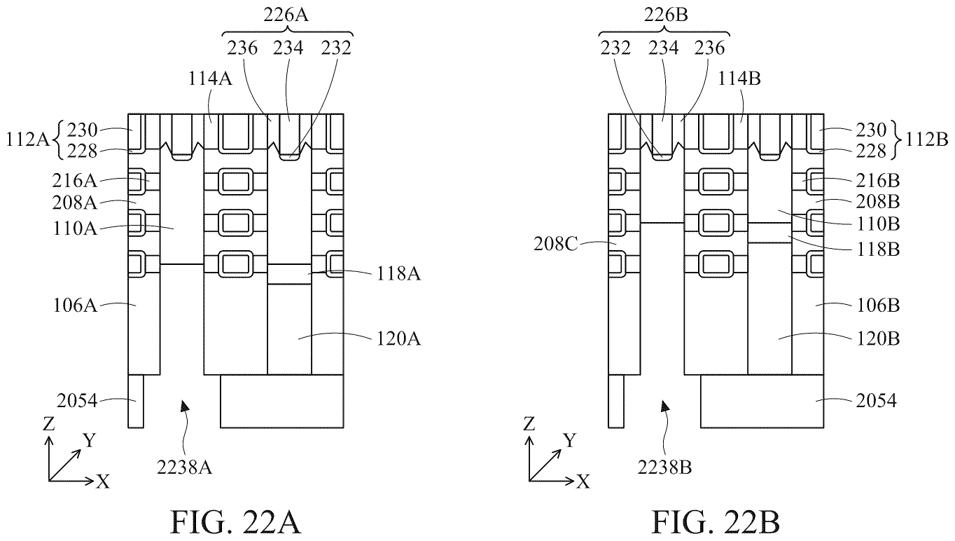

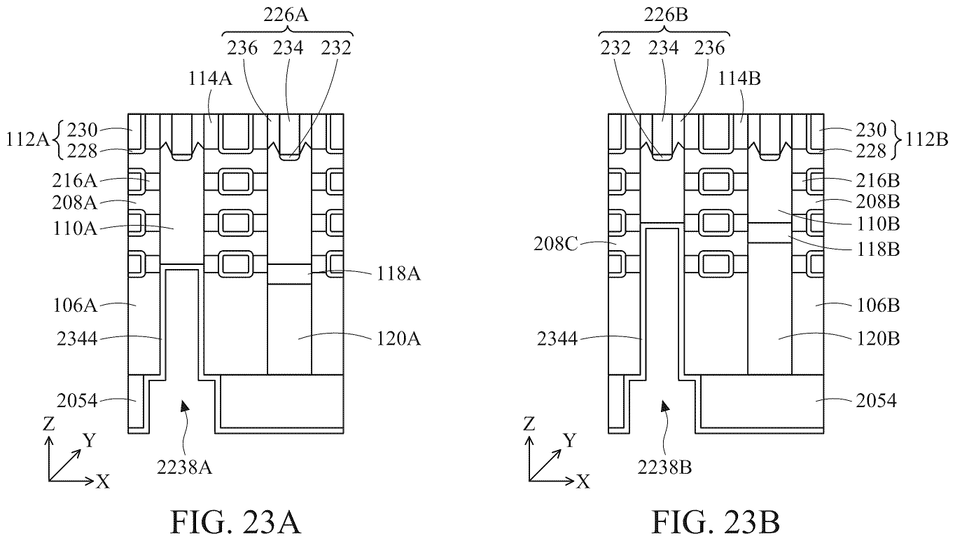

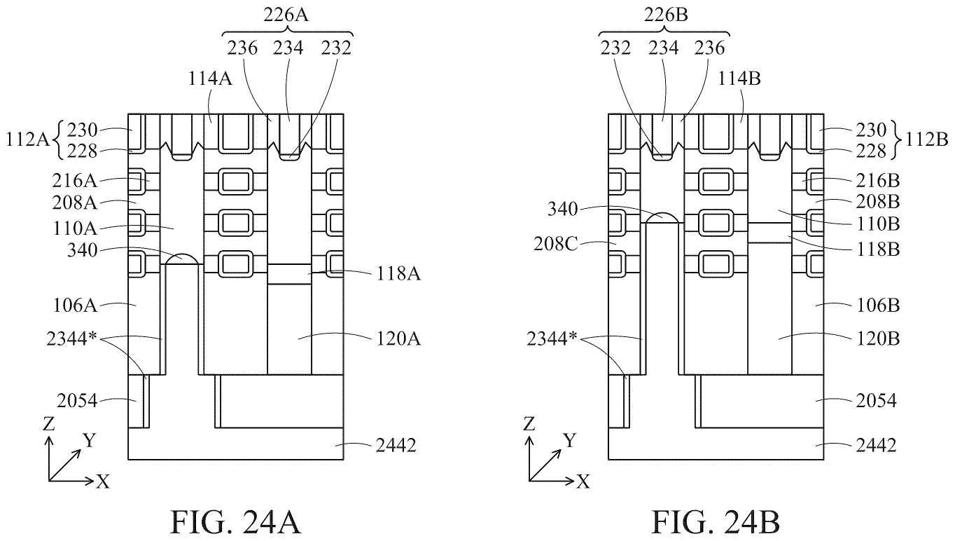

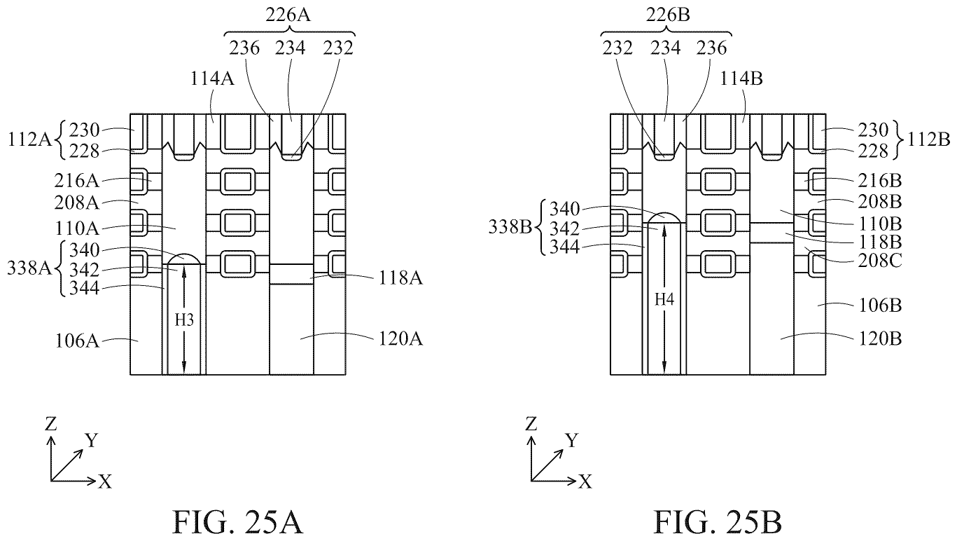

Referring to FIG. 7, in operation 735, BS contact structures are formed on one of the first S/D regions and on one of the second S/D regions. For example, as described with reference to FIGS. 19A-25A and 19B-25B, BS contact structure 338A is formed on the BS surface of one of S/D regions 110A and BS contact structure 338B is formed on the BS surface of one of S/D regions 110B. The formation of BS contact structures 338A and 338B can include sequential operations of (i) removing substrate 104 to expose back-side surfaces of base structures 106A and 106B and dummy epitaxial layers 120A and 120B, as shown in FIGS. 19A and 19B, (ii) depositing a hard mask layer 2054 (e.g., a SiN layer) on the back-side surfaces of base structures 106A and 106B and dummy epitaxial layers 120A and 120B, as shown in FIGS. 20A and 20B, (iii) forming openings 2138A and 2138B in hard mask layer 2054 using a photolithographic patterning process and etching process, as shown in FIGS. 21A and 21B, (iv) etching dummy epitaxial layers 120A and 120B through openings 2138A and 2138B, respectively, as shown in FIGS. 22A and 22B, (v) etching BS ESLs 118A and 118B through openings 2138A and 2138B, respectively, to form contact openings 2238A and 2238B, as shown in FIGS. 22A and 22B, (vi) depositing a dielectric layer 2344 having the material of dielectric liner 344 on hard mask layer 2054 and in openings 2238A and 2238B, as shown in FIGS. 23A and 23B, (vii) removing (e.g., by etching) horizontal portions of dielectric layer 2344 without removing the vertical portions of dielectric layer 2344 to form dielectric layer 2344*, as shown in FIGS. 24A and 24B, (viii) forming silicide layers 340, as shown in FIGS. 24A and 24B, (ix) depositing a conductive layer 2442 having the material of contact plug 342 to fill openings 2238A and 2238B, as shown in FIGS. 24A and 24B, and (x) performing a chemical mechanical polishing (CMP) process on the structures of FIGS. 24A and 24B to coplanarize back-side surfaces of base structures 106A and 106B, contact plugs 342, dielectric liners 344, and dummy epitaxial layers 120A and 120B, as shown in FIGS. 25A and 25B. With the use of dummy epitaxial layers 120A and 120B, self-aligned BS contact structures 338A and 338B of different heights can be formed in GAA FETs 102A and 102B at the same time, as shown in FIGS. 25A and 25B. In some embodiments, barrier layers 446 can be formed after forming silicide layers 340 and prior to depositing conductive layer 2442.

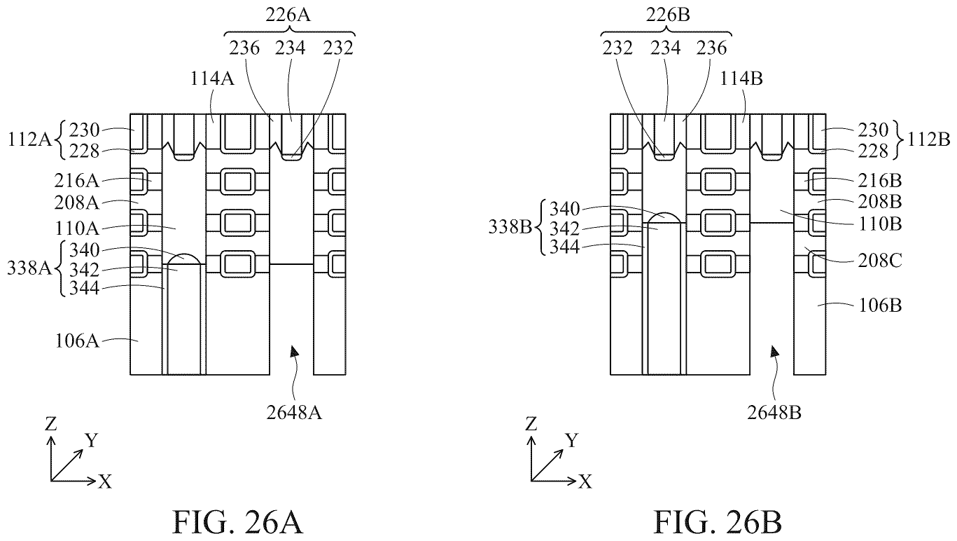

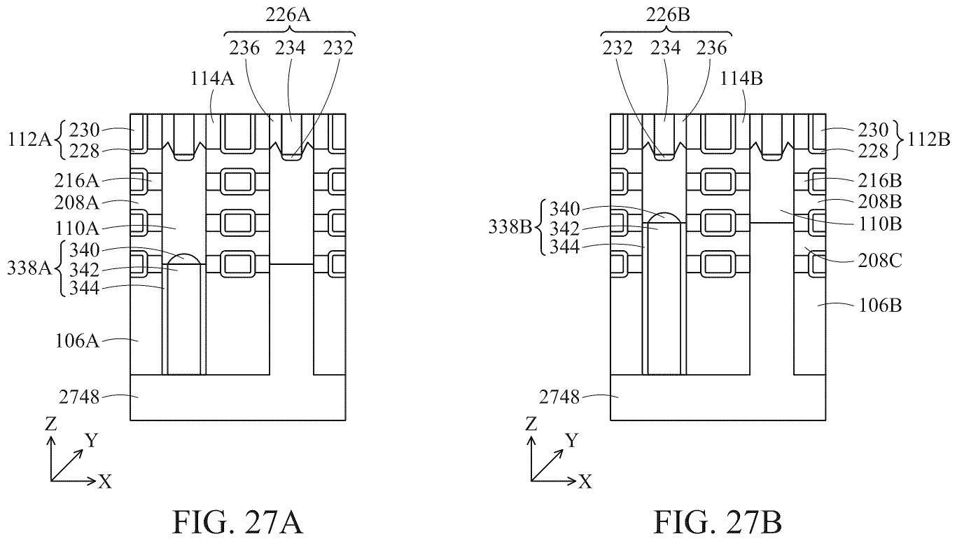

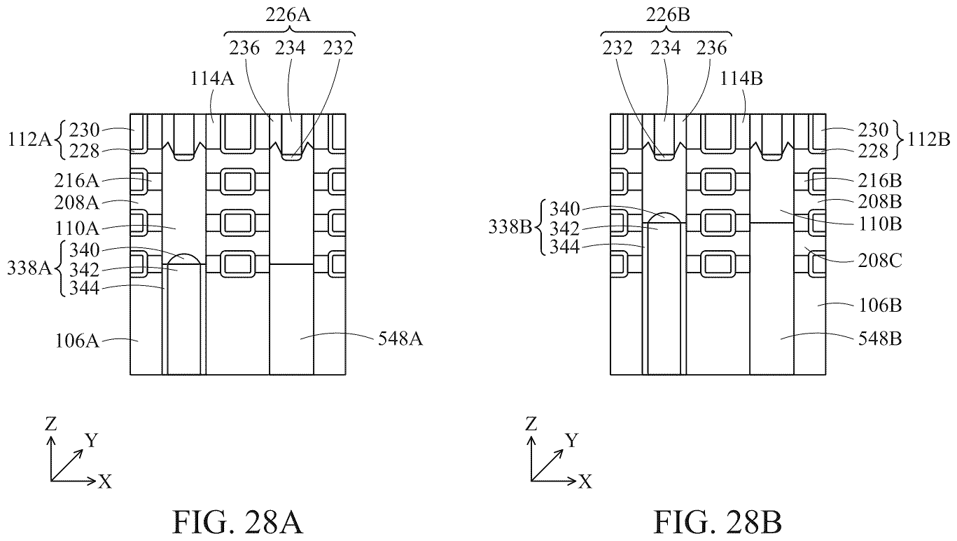

Referring to FIG. 7, in operation 740, BS isolation layers are formed on another one of the first S/D regions and on another one of the second S/D regions. For example, as described with reference to FIGS. 26A-28A and 26B-28B, BS isolation layer 548A is formed on the BS surface of another one of S/D regions 110A and BS isolation layer 548B is formed on the BS surface of another one of S/D regions 110B. The formation of BS isolation layers 548A and 548B can include sequential operations of (i) etching dummy epitaxial layers 120A and 120B and BS ESLs 118A and 118B from the structures of FIGS. 25A and 25B to form isolation openings 2648A and 2648B, as shown in FIGS. 26A and 26B, (ii) depositing a dielectric layer 2748 having the material of BS isolation layers 548A and 548B to fill openings 2648A and 2648B, as shown in FIGS. 27A and 27B, and (iii) performing a CMP process on dielectric layer 2748 to coplanarize back-side surfaces of base structures 106A and 106B, contact plugs 342, dielectric liners 344, and BS isolation layers 548A and 548B, as shown in FIGS. 28A and 28B. With the use of dummy epitaxial layers 120A and 120B, self-aligned BS isolation layers 548A and 548B of different heights can be formed in GAA FETs 102A and 102B at the same time, as shown in FIGS. 28A and 28B.

The present disclosure provides example structures of GAA FETs (e.g., GAA FETs 102A and 102B) with different drive current characteristics on a same substrate (e.g., substrate 104) of a semiconductor device (e.g., semiconductor device 100) and also provides examples methods (e.g., method 700) of fabricating these GAA FETs. In some embodiments, a first GAA FET (e.g., GAA FET 102A) can have first nanostructured layers (e.g., nanostructured layers 208A) between a first pair of S/D regions (e.g., S/D regions 110A) and a second GAA FET (e.g., GAA FET 102B) can have second nanostructured layers (e.g., nanostructured layers 208B) between a second pair of S/D regions (e.g., S/D regions 110B). The number of first nanostructured layers can be greater than the number of second nanostructured layers to achieve a higher drive current in the first GAA FET than in the second GAA FET. The semiconductor device can have GAA FETs of different drive current values to optimize the overall power consumption of the semiconductor device. In some embodiments, the number of first and second nanostructured layers that are in contact with the first and second pairs of S/D regions can be controlled with the use of first and second electrically inactive (“dummy”) epitaxial layers (e.g., dummy epitaxial layers 120A and 120B) disposed below the first and second pairs of S/D regions. In some embodiments, the first and second dummy epitaxial layers can also be used to form self-aligned back-side contact structures (e.g., BS contact structures 338A and 338B) on back-side surfaces of the first and second pairs of S/D regions. In some embodiments, the first and second dummy epitaxial layers can be replaced with back-side isolation layers (e.g., BS isolation layers 548A and 548B) to reduce current leakage from the first and second pairs of S/D regions to the substrate.

In some embodiments, a semiconductor device includes first and second base structures, first and second dummy epitaxial layers disposed in the first and second base structures, respectively, first and second active epitaxial layers disposed on the first and second dummy epitaxial layers, respectively, a first active nanostructured layer disposed adjacent to and in contact with the first active epitaxial layer, a second active nanostructured layer disposed adjacent to and in contact with the second active epitaxial layer, a dummy nanostructured layer disposed adjacent to and in contact with the second dummy epitaxial layer, a first gate structure surrounding the first active nanostructured layer, and a second gate structure surrounding the second active nanostructured layer and the dummy nanostructured layer. A height of the second dummy epitaxial layer is greater than a height of the first dummy epitaxial layer. A height of the first active epitaxial layer is greater than a height of the second active epitaxial layer.

In some embodiments, a semiconductor device includes a base structure, a dummy nanostructured layer disposed on the base structure, an active nanostructured layer disposed on the dummy nanostructured layer, a first S/D disposed adjacent to a first end of the active nanostructured layer, a second S/D region disposed adjacent to a second end of the active nanostructured layer, an isolation layer disposed on a BS of the first S/D region, a first contact structure disposed on a FS of the first S/D region, a second contact structure disposed on a BS of the second S/D region, and a gate structure surrounding the active nanostructured layer and the dummy nanostructured layer.

In some embodiments, a method includes forming a superlattice structure having a first nanostructured layer, a nanostructured sacrificial layer on the first nanostructured layer, and a second nanostructured layer on the nanostructured sacrificial layer, forming a polysilicon layer on the superlattice structure, forming first and second openings in the superlattice structure, epitaxially growing first and second semiconductor layers in the first and second openings, respectively, epitaxially growing third and fourth semiconductor layers on the first and second semiconductor layers, respectively, replacing the polysilicon layer and the nanostructured sacrificial layer with a gate structure, and replacing the first semiconductor layer with a contact structure on a BS of the third semiconductor layer. The first and second semiconductor layers are in contact with sidewalls of the first nanostructured layer. The third and fourth semiconductor layers are in contact with the second nanostructured layer and the nanostructured sacrificial layer.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
first and second base structures;
first and second dummy layers disposed in the first and second base structures, respectively, wherein a height of the second dummy layer is greater than a height of the first dummy layer;
first and second active epitaxial layers disposed on the first and second dummy layers, respectively, wherein a height of the first active epitaxial layer is greater than a height of the second active epitaxial layer;
a first active nanostructured layer disposed adjacent to and in contact with the first active epitaxial layer;
a second active nanostructured layer disposed adjacent to and in contact with the second active epitaxial layer;
a dummy nanostructured layer disposed adjacent to and in contact with the second dummy layer;
a first gate structure surrounding the first active nanostructured layer; and
a second gate structure surrounding the second active nanostructured layer and the dummy nanostructured layer.

2. The semiconductor device of claim 1, further comprising a semiconductor layer disposed between the first active epitaxial layer and the first dummy layer.

3. The semiconductor device of claim 1, further comprising a dielectric layer disposed between the first active epitaxial layer and the first dummy layer.

4. The semiconductor device of claim 1, further comprising a semiconductor layer disposed between the second active epitaxial layer and the second dummy layer and in contact with the dummy nanostructured layer.

5. The semiconductor device of claim 1, further comprising a dielectric layer disposed between the second active epitaxial layer and the second dummy layer and in contact with the dummy nanostructured layer.

6. The semiconductor device of claim 1, further comprising:
a first conductive structure disposed in the first base structure; and
a second conductive structure disposed in the second base structure, wherein the a height of the second conductive structure is greater than a height of the first conductive structure.

7. The semiconductor device of claim 1, further comprising a conductive structure disposed in the second base structure, wherein the dummy nanostructured layer is disposed between the conductive structure and the second dummy layer.

8. The semiconductor device of claim 1, further comprising third and fourth active epitaxial layers, wherein:
the first active nanostructured layer is disposed between and in contact with the first and third active epitaxial layers, and
the second active nanostructured layer is disposed between and in contact with the second and fourth active epitaxial layers.

9. The semiconductor device of claim 1, wherein a material of the first dummy layer is different from a material of the first active epitaxial layer.

10. The semiconductor device of claim 1, wherein the second active nanostructured layer and the dummy nanostructured layer comprise a same semiconductor material.

11. A semiconductor device, comprising:
a base structure;
a dummy nanostructured layer disposed on the base structure;
an active nanostructured layer disposed on the dummy nanostructured layer;
a first source/drain (S/D) disposed adjacent to a first end of the active nanostructured layer;
a second S/D region disposed adjacent to a second end of the active nanostructured layer;
an isolation layer disposed on a back-side of the first S/D region;
a first contact structure disposed on a front-side of the first S/D region;
a second contact structure disposed on a back-side of the second S/D region; and
a gate structure surrounding the active nanostructured layer and the dummy nanostructured layer.

12. The semiconductor device of claim 11, wherein the isolation layer comprises a dielectric layer.

13. The semiconductor device of claim 11, wherein the dummy nanostructured layer is disposed between and in contact with the isolation layer and the second contact structure.

14. The semiconductor device of claim 11, wherein the active nanostructured layer is in contact with the first and second S/D regions.

15. The semiconductor device of claim 11, further comprising an inner gate spacer in contact with the isolation layer.

16. The semiconductor device of claim 11, further comprising an inner gate spacer in contact with the second contact structure.

17. A method, comprising:
forming, on a substrate, a superlattice structure comprising a first nanostructured layer, a nanostructured sacrificial layer on the first nanostructured layer, and a second nanostructured layer on the nanostructured sacrificial layer;
forming a polysilicon layer on the superlattice structure;
forming first and second openings in the superlattice structure;
epitaxially growing first and second semiconductor layers in the first and second openings, respectively, wherein the first and second semiconductor layers are in contact with sidewalls of the first nanostructured layer;
epitaxially growing third and fourth semiconductor layers on the first and second semiconductor layers, respectively, wherein the third and fourth semiconductor layers are in contact with the second nanostructured layer and the nanostructured sacrificial layer;
replacing the polysilicon layer and the nanostructured sacrificial layer with a gate structure; and
replacing the first semiconductor layer with a contact structure on a back-side of the third semiconductor layer.

18. The method of claim 17, further comprising replacing the second semiconductor layer with a dielectric layer on a back-side of the fourth semiconductor layer.

19. The method of claim 17, further comprising removing the substrate prior to replacing the first semiconductor layer.

20. The method of claim 17, further comprising depositing first and second dielectric layers on the first and second semiconductor layers, respectively, prior to epitaxially growing third and fourth semiconductor layers.
